(19) United States
(12) Patent Application Publication
(10) Pub. No.: US 2019/0288098 A1
(43) Pub. Date: Sep. 19, 2019

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Hitoshi KOBAYASHI, Yamato Kanagawa (JP)

(73) Assignees: Kabushiki Kaisha Toshiba, Tokyo (JP); Toshiba Electronic Devices & Storage Corporation, Tokyo (JP)

(21) Appl. No.: 16/119,844

(22) Filed: Aug. 31, 2018

(30) Foreign Application Priority Data
Mar. 19, 2018 (JP) 2018-050873

(51) Int. Cl. H01L 29/778; H01L 29/20; H01L 29/417; H01L 29/423

(52) U.S. Cl. CPC H01L 29/778; H01L 29/42356; H01L 29/41775; H01L 29/2003

(57) ABSTRACT

A semiconductor device of an embodiment includes a nitride semiconductor layer, a source electrode provided in a first region and a second region on the nitride semiconductor layer, a drain electrode provided in the first region and the second region, an insulating film provided in the first region and the second region between the source electrode and the drain electrode, and a gate electrode provided in the first region and the second region on the nitride semiconductor layer between the source electrode and the drain electrode. A first distance between the source electrode and the drain electrode in a gate length direction of the first region is shorter than a second distance between the source electrode and the drain electrode in a gate length direction of the second region. A first length of the insulating film in the gate length direction of the first region is shorter than a second length of the insulating film in the gate length direction of the second region.

### CROSS-REFERENCE TO RELATED APPLICATION

This application is based upon and claims the benefit of priority from Japanese Patent Application No. 2018-050873, filed on Mar. 19, 2018, the entire contents of which are incorporated herein by reference.

### FIELD

Embodiments described herein relate generally to a semiconductor device.

### BACKGROUND

A nitride semiconductor transistor has a high dielectric breakdown strength. However, when a high voltage is applied to the nitride semiconductor transistor, a phenomenon called current collapse where the on-resistance increases and the drain current decreases becomes remarkable.

The current collapse degrades the performance of the transistor. Therefore, it is desired to suppress the current collapse to realize a high-performance transistor.

### BRIEF DESCRIPTION OF THE DRAWINGS

FIGS. 1A to 1D are schematic diagrams of a semiconductor device of a first embodiment;

FIGS. 2A and 2B are schematic diagrams of a main portion of the semiconductor device of the first embodiment;

FIGS. 3A and 3B are schematic diagrams showing a part of a manufacturing process in a manufacturing method of the first embodiment;

FIGS. 4A and 4B are schematic diagrams showing a part of a drain electrode manufacturing process in a description of function and effect of the first embodiment;

FIGS. 5A to 5D are schematic diagrams of a semiconductor device of a second embodiment;

FIG. 6 is a schematic diagram showing a part of the semiconductor device of the second embodiment;

FIGS. 7A and 7B are schematic diagrams showing a part of a manufacturing process in a manufacturing method of the second embodiment; and

FIGS. 8A to 8D are schematic diagrams of a semiconductor device of a third embodiment.

### DETAILED DESCRIPTION

A semiconductor device of an embodiment includes a nitride semiconductor layer, a source electrode provided in a first region and a second region on the nitride semiconductor layer, a drain electrode provided in the first region and the second region, an insulating film provided in the first region and the second region between the source electrode and the drain electrode, and a gate electrode provided in the first region and the second region on the nitride semiconductor layer between the source electrode and the drain electrode. A first distance between the source electrode and the drain electrode in a gate length direction of the first region is shorter than a second distance between the source electrode and the drain electrode in a gate length direction of the second region. A first length of the insulating film in the gate length direction of the first region is shorter than a second length of the insulating film in the gate length direction of the second region.

Hereinafter, the embodiment will be described with reference to the drawings. In the drawings, the same or similar portions are denoted by the same or similar symbols.

In the present specification, the same or similar members are denoted by the same symbols and redundant descriptions will be omitted.

In the present specification, a “nitride (GaN-based) semiconductor” is a collective term of semiconductors including gallium nitride (GaN), aluminum nitride (AlN), indium nitride (InN) and/or their intermediate composition.

In the present, specification, “undoped” means that an impurity concentration is 1×10¹⁵ cm⁻³ or less.

In the present specification, in order to show a positional relationship of components or the like, a portion in an upward direction in a drawing is written as an “upper portion” and a portion in a downward direction in a drawing is written as a “lower portion”. In the present specification, the concepts of the “upper portion” and the “lower portion” are not terms indicating a relationship with respect to the direction of the gravity.

### First Embodiment

A semiconductor device of the present embodiment includes a nitride semiconductor layer, a source electrode provided in a first region and a second region on the nitride semiconductor layer, a drain electrode provided in the first region and the second region, an insulating film provided in the first region and the second region between the source electrode and the drain electrode, and a gate electrode provided in the first region and the second region on the nitride semiconductor layer between the source electrode and the drain electrode. A first distance between the source electrode and the drain electrode in a gate length direction of the first region is shorter than a second distance between the source electrode and the drain electrode in a gate length direction of the second region. A first length of the insulating film in the gate length direction of the first region is shorter than a second length of the insulating film in the gate length direction of the second region.

Further, a semiconductor device of the present embodiment includes a nitride semiconductor layer, a first source electrode provided in a first region and a second region on the nitride semiconductor layer, a second source electrode provided in the first region and the second region on the nitride semiconductor layer, a drain electrode provided in the first region and the second region between the first source electrode and the second source electrode, a first insulating film provided in the first region and the second region between the first source electrode and the drain electrode, a sixth insulating film provided in the first region and the second region between the second source electrode and the drain electrode, a first gate electrode provided in the first region and the second region on the first insulating film, and a sixth gate electrode provided in the first region and the second region on the sixth insulating film. A first distance between the first source electrode and the drain electrode in a gate length direction of the first region is shorter than a second distance between the first source electrode and the drain electrode in the gate length direction of the second region. A first length of the first insulating film in the gate length direction of the first region is shorter than a second length of the second insulating film in the gate length direction of the second region. A third distance between the second source electrode and the drain electrode in the gate length direction of the first region is shorter than a fourth distance between the second source electrode and the drain electrode in the gate length direction of the second region. A third length of the sixth insulating film in the gate length direction of the first region is shorter than a fourth length of the sixth insulating film in the gate length direction of the second region.

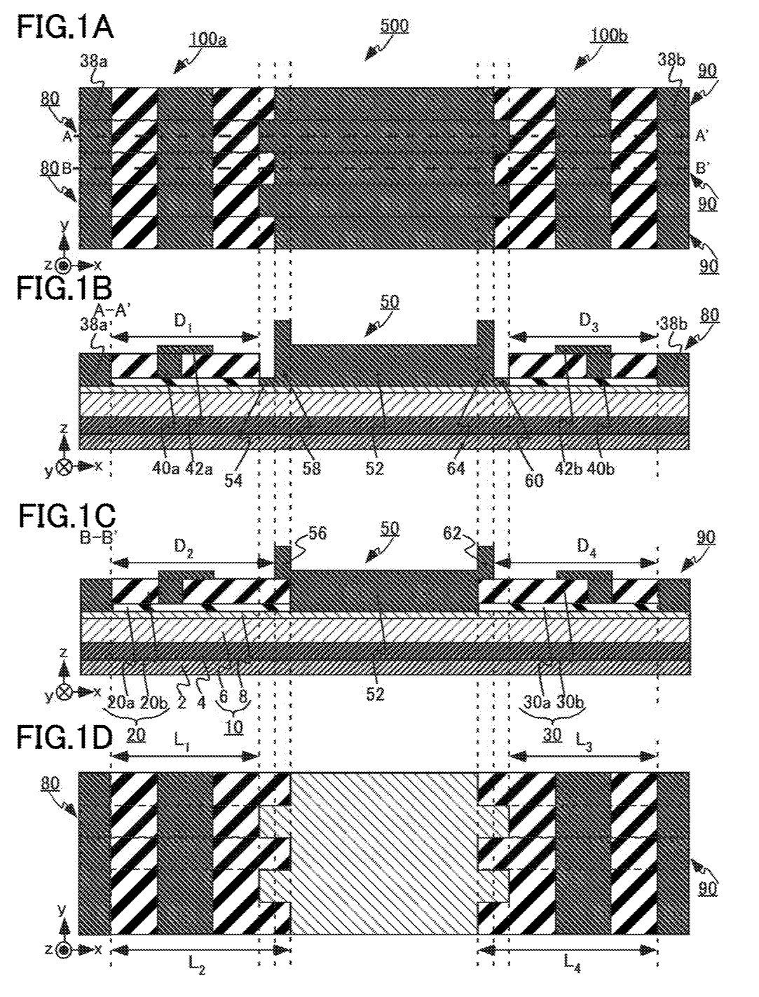

FIGS. 1A to 1D are schematic diagrams of a first semiconductor device 100a, a second semiconductor device 100b, and a third semiconductor device 500 of the present embodiment.

Each of the first semiconductor device 100a and the second semiconductor device 100b is high electron mobility transistor (HEMT) using a nitride semiconductor using a common drain electrode 50. The third semiconductor device 500 is a semiconductor device including the first semiconductor device 100a and the second semiconductor device 100b. FIG. 1A is a schematic top view of the third semiconductor device 500 (the first semiconductor device 100a and the second semiconductor device 100b). FIG. 1B is a schematic cross-sectional view of the third semiconductor device 500 (the first semiconductor device 100a and the second semiconductor device 100b) taken along line A-A′ shown in FIG. 1A perpendicular to the paper surface. FIG. 1C is a schematic cross-sectional view of the third semiconductor device 500 (the first semiconductor device 100a and the second semiconductor device 100b) taken along line B-B′ shown in FIG. 1A perpendicular to the paper surface. FIG. 1D is a schematic top view of the third semiconductor device 500 (the first semiconductor device 100a and the second semiconductor device 100b) shown in FIG. 1A from which the drain electrode 50 is removed.

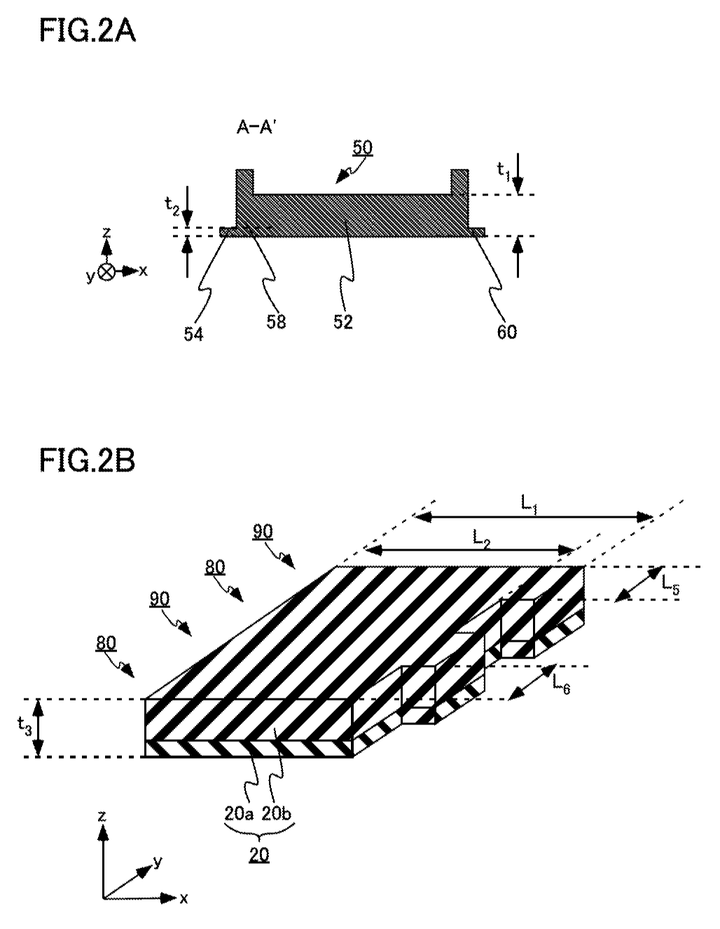

FIGS. 2A and 2B are schematic diagrams of a part of the semi conductor device of the present embodiment. FIG. 2A is a schematic cross-sectional view of the drain electrode 50 taken along cross-section A-A′ in a first region 80. FIG. 2B is a schematic diagram of a first insulating film 20.

The first semiconductor device (semiconductor device) 100a includes a substrate 2, a buffer layer (third semiconductor layer) 4, a nitride semiconductor layer 10, a first source electrode (source electrode) 38a, a drain electrode 50, a first insulating film 20, a first gate electrode (gate electrode) 40a, and a first gate field plate electrode (gate field plate electrode) 42a.

The nitride semiconductor layer 10 has a first semiconductor layer 6 and a second semiconductor layer 8.

The first insulating film 20 has a CVD nitride film 20a and a PE nitride film 20b.

The second semiconductor device (semiconductor device) 100b includes the substrate 2, the buffer layer (third semiconductor layer) 4, the nitride semiconductor layer 10, a second source electrode 38b, the drain electrode 50, a sixth insulating film (second insulating film) 30, a second gate electrode 40b, and a second gate field plate electrode 42b.

The sixth insulating film 30 has a CVD nitride film 30a and a PE nitride film 30b.

As the substrate 2, a substrate with a low resistance value is preferably used. For example, a semiconductor substrate which contains a p-type impurity or an n-type impurity and has a low resistance value is preferably used as the substrate of the present embodiment. Specifically, a silicon (Si) substrate or a silicon carbide (SiC) substrate is preferably used. Here, the p-type impurity used for the Si substrate is, for example, boron (B) or aluminum (Al), and the n-type impurity used for the Si substrate is, for example, phosphorus (P) or arsenic (As). Further, the p-type impurity used for the SiC substrate is, for example, B or Al, and the n-type impurity used for the SiC substrate is, for example, nitrogen (N).

The nitride semiconductor layer 10 has the first semiconductor layer 6 and the second semiconductor layer 8 which is provided on the first semiconductor layer 6 and has a band gap greater than that of the first semiconductor layer 6. Thus, a transistor having a HEMT structure having a high mobility is created.

The first semiconductor layer 6 is, for example, undoped AlₓGa₁₋ₓN (0≤X<1). More specifically, the first semiconductor layer 6 is, for example, undoped GaN. The film thickness of the first semiconductor layer 6 is, for example, 0.5 μm or more and 3 μm or less.

The second semiconductor layer 8 is, for example, undoped Al_{y}Ga_{1-y}N (0<Y≤1 and X<Y). More specifically, the second semiconductor layer 8 is, for example, undoped Al_{0.2}Ga_{0.8}N The film thickness of the second semiconductor layer 8 is, for example, 15 nm or more and 50 nm or less.

A heterojunction interface is formed between the first semiconductor layer 6 and the second semiconductor layer 8. When the first semiconductor device 100a is in an on-operation state, a two dimensional electron gas (2DEG) is formed at the heterojunction interface to be a carrier.

The buffer layer 4 is provided between the substrate 2 and the nitride semiconductor layer 10. The buffer layer 4 has a function to reduce a lattice mismatch between the substrate 2 and the nitride semiconductor layer 10. The buffer layer 4 is formed by, for example, a multilayer structure of aluminum gallium nitride (Al_{w}Ga_{1-w}N (0<W<1)).

Here, an x direction, a y direction that is one direction perpendicular to the x direction, and a z direction perpendicular to the x direction and the y direction are defined. The substrate 2, the buffer layer 4, the first semiconductor layer 6, and the second semiconductor layer 8 are provided in parallel with an xy plane. A gate length direction of the first semiconductor device 100a and the second semiconductor device 100b is in parallel with the x direction. A gate width direction of the first semiconductor device 100a and the second semiconductor device 100b is in parallel with the y direction.

The first, regions 80 and second regions 90 are alternately provided in the y direction (gate width direction) on the nitride semiconductor layer 10.

A first source electrode 38a is provided in the first region 80 and the second region 90 on the nitride semiconductor layer 10.

A second source electrode 38b is provided in the first region 80 and the second region 90 on the nitride semiconductor layer 10.

The drain electrode 50 is provided in the first region 80 and the second region 90 between the first source electrode 38a and the second source electrode 38b.

The first insulating film 20 is provided in the first region 80 and the second region 90 between the first source electrode 38a and the drain electrode 50.

The sixth insulating film 30 is provided in the first region 80 and the second region 90 between the second source electrode 38b and the drain electrode 50.

A first gate electrode 40a is provided in the first region 80 and the second region 90 on the nitride semiconductor layer 10 between the first source electrode 38a and the drain electrode 50. For example, the first gate electrode 40a is provided on the CVD nitride film 20a.

The second gate electrode 40b is provided in the first region 80 and the second region 90 on the nitride semiconductor layer 10 between the second source electrode 38b and the drain electrode 50. For example, the second gate electrode 40b is provided on the CVD nitride film 30a.

The first source electrode 38a, the second source electrode 38b, the first gate electrode 40a, the second gate electrode 40b, and the drain electrode 50 are, for example, metal electrodes. The metal electrode here has, for example, a stacked structure of titanium (Ti) and aluminum (Al) or a stacked structure of nickel (Ni) and gold (Au). It is preferable that the nitride semiconductor layer 10 is ohmic-joined with the first source electrode 38a, the second source electrode 38b, and the drain electrode 50. It is preferable that a distance between the first source electrode 38a and the drain electrode 50 and a distance between the second source electrode 38b and the drain electrode 50 are, for example, 5 μm or more and 30 μm or less.

The first insulating film 20 has the CVD nitride film 20a formed by a low-temperature chemical vapor deposition (CVD) method and the PE nitride film 20b that is formed by a plasma CVD method and provided on the CVD nitride film 20a.

The sixth insulating film 30 has the CVD nitride film 30a formed by the low-temperature chemical vapor deposition (CVD) method and the PE nitride film 30b that is formed by the plasma CVD method and provided on the CVD nitride film 30a.

The first gate field plate electrode (gate field plate electrode) 42a is provided on the first insulating film 20 (the PE nitride film 20b). The first gate field plate electrode 42a is used for electric field relaxation in the first semiconductor device 100a.

The second gate field plate electrode 42b is provided on the sixth insulating film 30 (the PE nitride film 30b). The second gate field plate electrode 42b is used for electric field relaxation in the second semiconductor device 100b.

A first distance D₁ between the first source electrode 38a and the drain electrode 50 in the gate length direction (x direction) of the first region 80 is shorter than a second distance D₂ between the first source electrode 38a and the drain electrode 50 in the gate length direction (x direction) of the second region 90.

Further, a first length L₁ of the first insulating film 20 in the gate length direction (x direction) of the first region 80 is shorter than a second length L₂ of the first insulating film 20 in the gate length direction (x direction) of the second region 90.

A third distance D₃ between the second source electrode 38b and the drain electrode 50 in the gate length direction (x direction) of the first region 80 is shorter than a fourth distance D₄ between the second source electrode 38b and the drain electrode 50 in the gate length direction (x direction) of the second region 90.

Further, a third length L₃ of the sixth insulating film 30 in the gate length direction (x direction) of the first region 80 is shorter than a fourth length L₄ of the sixth insulating film 30 in the gate length direction (x direction) of the second region 90.

The drain electrode 50 has a first electrode portion 52 provided in the first region 80 and the second region 90. Further, the drain electrode 50 has a second electrode portion 54 provided between the first electrode portion 52 in the first region 80 and the first insulating film 20 in the first region 80. Further, the drain electrode 50 has a third electrode portion 56 provided on the first insulating film 20 between the first electrode portion 52 in the second region 90 and the first gate electrode 40a in the second region 90. Further, the drain electrode 50 has a fourth electrode portion 58 provided between the first electrode portion 52 in the first region 80 and the second electrode portion 54 in the first region 80.

Further, the drain electrode 50 has a fifth electrode portion 60 provided between the first electrode portion 52 in the first region 80 and the sixth insulating film 30 in the first region 80. Further, the drain electrode 50 has a sixth electrode portion 62 provided on the sixth insulating film 30 between the first electrode portion 52 in the second region 90 and the second gate electrode 40b in the second region 90. Further, the drain electrode 50 has a seventh electrode portion 64 provided between the first electrode portion 52 in the first region 80 and the fifth electrode portion 60 in the first region 80.

A film thickness t₁ of the first electrode portion 52 is thicker than a film thickness t₁ of the second electrode portion 54 and the fifth electrode portion 60.

A ratio t₃/(L₁−L₂) between a film thickness t₃ of the first insulating film 20 and a difference between the first length L₁ of the first insulating film 20 in the gate length direction (x direction) of the first region 80 and the second length L₂ of the first insulating film 20 in the gate length direction (x direction) of the second region 90 is preferred to be greater than 0.5.

L₁−L₂ is, for example, about 0.5 μm. A length in the y direction of the first insulating film 20 in the first region 80 is, for example, about 0.4 μm. A length L₅ in the y direction of the first insulating film 20 in the second region 90 is, for example, about 0.3 μm. The same goes for the sixth insulating film 30.

Next, a manufacturing method of the semiconductor device of the present embodiment will be described.

First, the buffer layer 4 is formed on the substrate 2. Next, the nitride semiconductor layer 10 including the first semiconductor layer 6 and the second semiconductor layer 8 is sequentially formed on the buffer layer 4.

Next, the first source electrode 38a is formed in the first region 80 and the second region 90 of the nitride semiconductor layer 10. Next, the second source electrode 38b is formed in the first region 80 and the second region 90 of the nitride semiconductor layer 10.

Next, the first insulating film 20 where the first length L₁ in the gate length direction (x direction) of the first region 80 is shorter than the second length L₂ in the gate length direction (x direction) of the second region 90 is formed in the first region 80 and the second region 90 between the first source electrode 38a and the second source electrode 38b.

Further, the sixth insulating film 30 where the third length L₃ in the gate length direction (x direction) of the first region 80 is shorter than the fourth length L₄ in the gate length direction (x direction) of the second region 90 is formed in the first region 80 and the second region 90.

Next, the drain electrode 50 is formed in the first region 80 and the second region 90 between the first source electrode 38a and the second source electrode 38b.

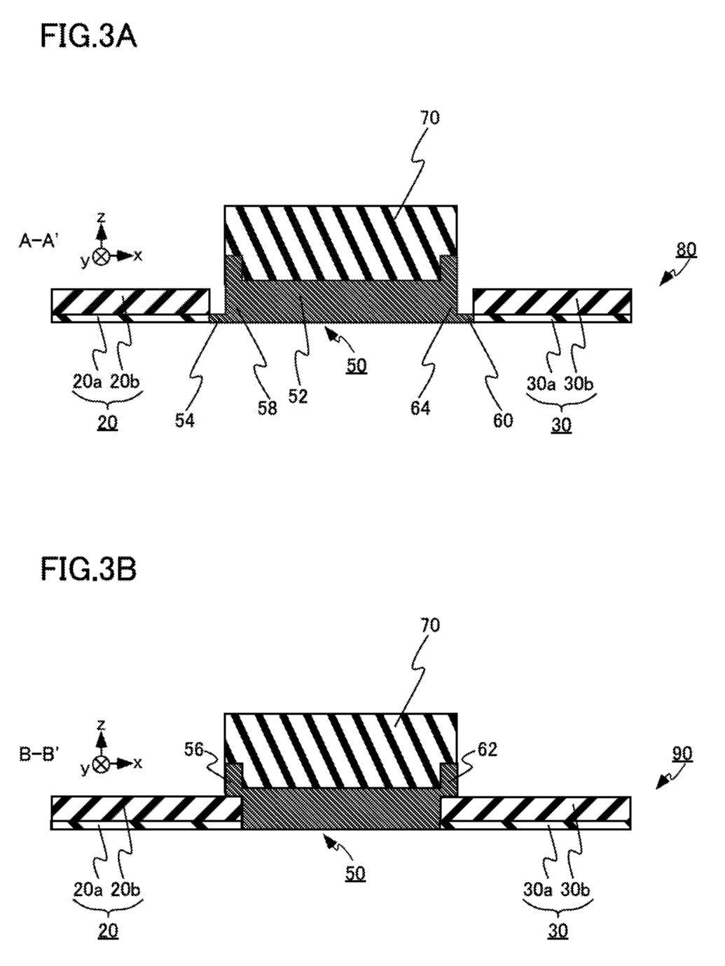

FIGS. 3A and 3B are schematic diagrams showing a part of a manufacturing process in the manufacturing method of the semiconductor device of the present embodiment. FIG. 3A is a schematic cross-sectional view showing a part of a manufacturing process of the drain electrode 50 in the first region 80. FIG. 3B is a schematic cross-sectional view showing a part of a manufacturing process of the drain electrode 50 in the second region 90.

An electrode material 72 composed of a stacked structure of titanium (Ti) and aluminum (Al) is formed on the first insulating film 20 and the sixth insulating film 30 on the nitride semiconductor layer 10, and on the nitride semiconductor layer 10 between the first insulating film 20 and the sixth insulating film 30. Next, a part of the electrode material 72 is removed by lithography and reactive ion etching (RIE).

At this time, in the first region 80, as shown in FIG. 3A, the second electrode portion 54 is formed in a region between the first electrode portion 52 and the first insulating film 20, which is not covered by a resist 70. Further, the fifth electrode portion 60 is formed in a region between the first electrode portion 52 and the sixth insulating film 30, which is not covered by the resist 70. Further, the fourth electrode portion 58 is formed under the resist 70 between the first electrode portion 52 and the second electrode portion 54, and the seventh electrode portion 64 is formed under the resist 70 between the first electrode portion 52 and the fifth electrode portion 60.

Further, in the second region 90, the third electrode portion 56 is formed on the first insulating film 20, and the sixth electrode portion 62 is formed on the sixth insulating film 30.

Next, the resist 70 is removed, and the first gate field plate electrode 42a electrically connected to the first gate electrode 40a and the second gate field plate electrode 42b electrically connected to the second gate electrode 40b are formed, so that the semiconductor device of the present embodiment is obtained.

Next, function and effect of the semiconductor device of the present embodiment will be described.

As a cause of the current collapse, it is considered that an electric field is concentrated to a part of the drain electrode 50 (that corresponds to the third electrode portion 56) provided on the first insulating film 20 and a part of the drain electrode 50 (that corresponds to the sixth electrode portion 62) provided on the sixth insulating film 30 and an electron trap occurs. When the electron trap occurs, a two dimensional electron gas (2DEG) is depleted and provided with high resistance, so that characteristics of the semiconductor device are degraded.

A semiconductor device that is not provided with the third electrode portion 56 and the sixth electrode portion 62 is considered. However, when the third electrode portion 56 and the sixth electrode portion 62 are simply not provided, the nitride semiconductor layer 10 between the first insulating film 20 and the drain electrode 50 and the nitride semiconductor layer 10 between the sixth insulating film 30 and the drain electrode 50 may be exposed, so that when the drain electrode 50 is processed by RIE or wet etching, an exposed part of the nitride semiconductor layer 10 is damaged. Therefore, there is a problem that the characteristics of the semiconductor device are degraded.

In the first semiconductor device 100a of the present embodiment, the first distance D₁ between the first source electrode 38a and the drain electrode 50 in the gate length direction (x direction) of the first region 80 is shorter than the second distance D₂ between the first source electrode 38a and the drain electrode 50 in the gate length direction (x direction) of the second region 90. Further, the first length L: of the first insulating film 20 in the gate length direction (x direction) of the first region 80 is shorter than the second length L₂ of the first insulating film 20 in the gate length direction (x direction) of the second region 90.

Further, the drain electrode 50 has the first electrode portion 52 provided in the first region 80 and the second region 90, and the second electrode portion 54 provided between the first electrode portion 52 in the first region 80 and the first insulating film 20 in the first region 80.

In the second region 90, the third electrode portion 56 is provided on the first insulating film 20. However, in the first region 80, the drain electrode 50 does not have a portion provided on the first insulating film 20. Therefore, it is possible to suppress generation of the current collapse.

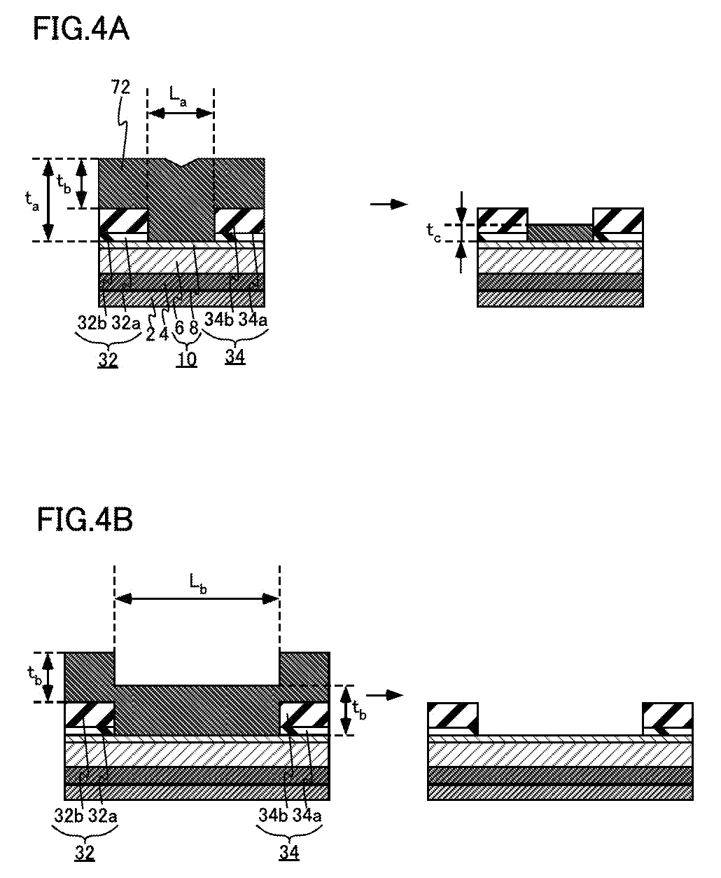

FIGS. 4A and 4B are schematic diagrams showing a part of a manufacturing process of the drain electrode 50 in a description of function and effect of the present embodiment.

As in FIG. 4A, when a distance between an insulating film 32 and an insulating film 34 is Lₐ which is short, even when the electrode material 72 is formed to have a film thickness t_{b}, a film thickness of an electrode material between the insulating film 32 and the insulating film 34 becomes tₐ thicker than t_{b} because the electrode material 72 on the insulating film 32 and the electrode material 72 on the insulating film 34 overlap with each other. As a result, even when the electrode material 72 on the insulating film 32 and the insulating film 34 is removed by RIE or the like, the electrode material 72 having a film thickness t_{c} thinner than the film thickness t_{b} is formed between the insulating film 32 and the insulating film 34. The second electrode portion 54 and the fifth electrode portion 60 which have a film thickness thinner than that of the first electrode portion 52 are formed by using the above principle. In this way, in the semiconductor device of the present embodiment, an electrode portion does not remain on the insulating films.

As in FIG. 4B, when the distance between the insulating film 32 and the insulating film 34 is L_{b} which is long, a film thickness of the electrode material 72 between the insulating film 32 and the insulating film 34 becomes t_{b} in the same manner as the electrode material 72 on the insulating film 32 and the insulating film 34. Therefore, when the electrode material 72 on the insulating film 32 and the insulating film 34 is removed by RIE or the like, the electrode material 72 between the insulating film 32 and the insulating film 34 is also removed. In this case, a portion to be a drain electrode cannot be left.

According to the semiconductor device of the present embodiment, it is possible to provide a semiconductor device that can suppress the current collapse.

### Second Embodiment

A semiconductor device of the present embodiment includes a nitride semiconductor layer, a source electrode provided in a first region and a second region on the nitride semiconductor layer, a drain electrode provided in the first region and the second region, a first insulating film provided in the first region and the second region between the source electrode and the drain electrode, a gate electrode provided in the first region and the second region on the nitride semiconductor layer between the source electrode and the drain electrode, a second insulating film provided in the drain electrode in the first region separately from the first insulating film, and a third insulating film provided in the drain electrode in the second region separately from the first insulating film and the second insulating film.

Further, a semiconductor device of the present embodiment includes a nitride semiconductor layer, a first source electrode provided in a first region and a second region on the nitride semiconductor layer, a second source electrode provided in the first region and the second region on the nitride semiconductor layer, a drain electrode provided in the first region and the second region between the first source electrode and the second source electrode, a first, insulating film provided in the first region and the second region between the first source electrode and the drain electrode, a sixth insulating film provided in the first region and the second region between the second source electrode and the drain electrode, a first gate electrode provided in the first region and the second region on the first insulating film, a sixth gate electrode provided in the first region and the second region on the sixth insulating film, a second insulating film provided in the drain electrode in the first region between the first insulating film and the sixth insulating film, a third insulating film provided in the drain electrode in the second region between the first insulating film and the sixth insulating film, a fourth insulating film provided in the drain electrode in the first region separately from the second insulating film, and a fifth insulating film provided in the drain electrode in the second region separately from the third insulating film.

Here, description of the same content as that of the first embodiment is omitted.

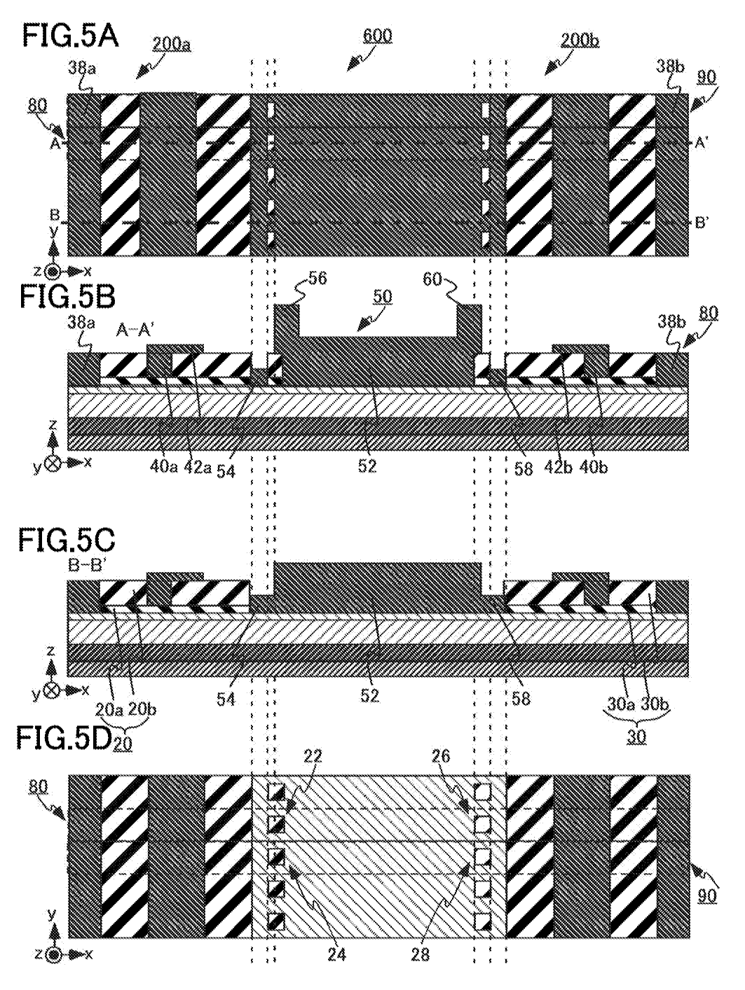

FIGS. 5A to 5D are schematic diagrams of a first semiconductor device 200a, a second semiconductor device 200b, and a third semiconductor device 600 of the present embodiment.

The first semiconductor device 200a and the second semiconductor device 200b are semiconductor devices using a common drain electrode 50. The third semiconductor device 600 is a semiconductor device including the first semiconductor device 200a and the second semiconductor device 200b. FIG. 5A is a schematic top view of the third semiconductor device 600 (the first semiconductor device 200a and the second semiconductor device 200b). FIG. 5B is a schematic cross-sectional view of the third semiconductor device 600 (the first semiconductor device 200a and the second semiconductor device 200b) taken along line A-A′ shown in FIG. 5A perpendicular to the paper surface. FIG. 5C is a schematic cross-sectional view of the third semiconductor device 600 (the first semiconductor device 200a and the second semiconductor device 200b) taken along line B-B′ shown in FIG. 5A perpendicular to the paper surface. FIG. 5D is a schematic top view of the third semiconductor device 600 (the first semiconductor device 200a and the second semiconductor device 200b) shown in FIG. 5A from which the drain electrode 50 is removed.

The first semiconductor device 200a of the present embodiment includes a second insulating film 22 provided in the drain electrode 50 in the first region 80 separately from the first insulating film 20, and a third insulating film 24 provided in the drain electrode 50 in the second region 90 separately from the first insulating film 20 and the second insulating film 22.

Further, the first semiconductor device 200a is provided with a fourth insulating film 26 provided in the drain electrode 50 in the first region 80 separately from the second insulating film 22, and a fifth insulating film 28 provided in the drain electrode 50 in the first region 80 separately from the third insulating film 24.

The second insulating film 22 and the third insulating film 24 are provided, so that the second electrode portion 54 can be formed between the second insulating film 22 and the first insulating film 20 in the first region 80 and between the third insulating film 24 and the first insulating film 20 in the second region 90. Different from the first embodiment, the third electrode portion 56 is not provided on the first insulating film 20 in the second region 90. Therefore, it is possible to further suppress the current collapse of the first semiconductor device 200a.

The fourth insulating film 26 and the fifth insulating film 28 are provided, so that the fourth electrode portion 58 can be formed between the fourth insulating film 26 and the sixth insulating film 30 in the first region 80 and between the fifth insulating film 28 and the sixth insulating film 30 in the second region 90. As in the first embodiment, the fifth electrode portion 60 is not provided on the sixth insulating film 30 in the second region 90. Therefore, it is possible to further suppress the current collapse of the second semiconductor device 200b.

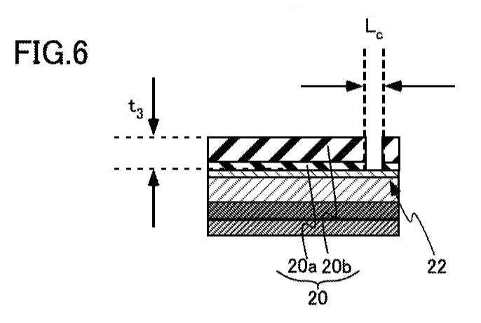

FIG. 6 is a schematic diagram showing a part of the semiconductor device of the present embodiment.

To satisfactorily form the second electrode portion 54, a ratio t₃/L_{c} between a film thickness t₃ of the first insulating film 20 and the second insulating film 22 and a distance L_{c} between the first insulating film 20 and the second insulating film 22 is preferred to be greater than 0.5. The same goes for the sixth insulating film 30 and the fifth insulating film 28.

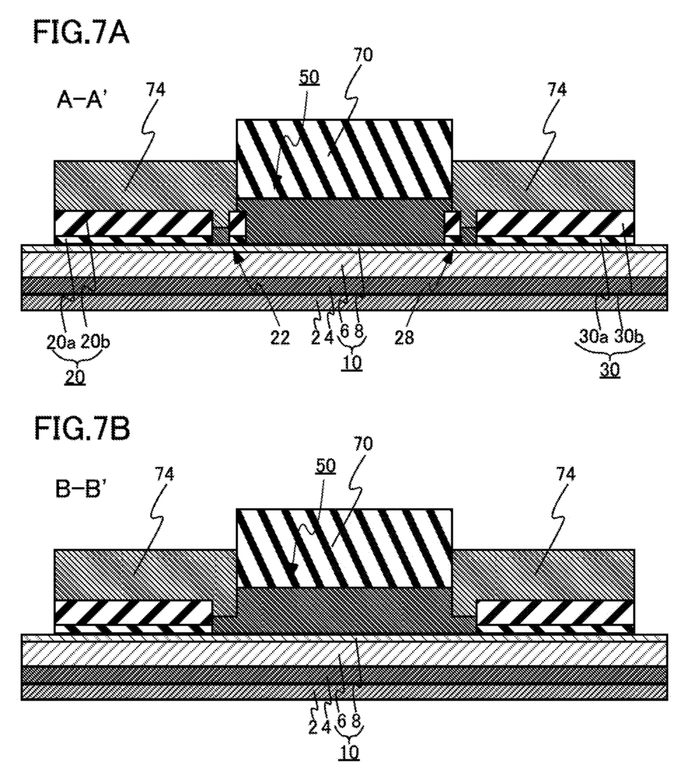

FIGS. 7A and 73 are schematic diagrams showing a part of a manufacturing process in a manufacturing method of the semi conductor device of the present embodiment. The drain electrode 50 is formed by removing the electrode material 72 to be removed by RIE or the like.

According to the semiconductor device of the present embodiment, it is possible to provide a semiconductor device that can further suppress the current collapse.

### Third Embodiment

A semiconductor device of the present embodiment is different from the second semiconductor device in that the second insulating film 22 and the fourth insulating film 26 are integrally provided and the third insulating film 24 and the fifth insulating film 28 are integrally provided. Here, description of the same content as that of the first and the second embodiments is omitted.

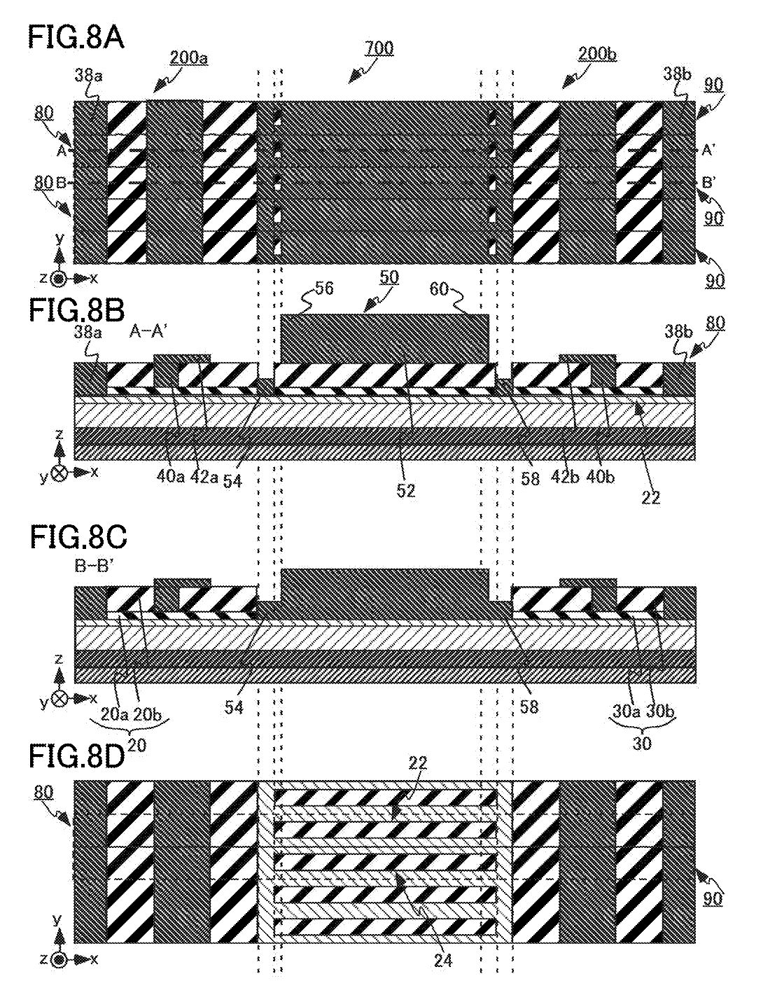

FIGS. 8A to 8D are schematic diagrams of a semiconductor device 700 of the present embodiment.

The second insulating film 22 and the fourth insulating film 26 are integrally provided and the third insulating film 24 and the fifth insulating film 28 are integrally provided. Therefore, the insulating films can be formed easier than those of the semiconductor device of the second embodiment.

On the other hand, the semiconductor device of the second embodiment is excellent in electrical characteristics because the nitride semiconductor layer 10 and the drain electrode 50 are in contact with each other between the second insulating film 22 and the fifth insulating film 28 and between the third insulating film 24 and the fifth insulating film 28.

According to the semiconductor device of the present embodiment, it is possible to provide a semiconductor device that can further suppress the current collapse.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a nitride semiconductor layer;
a source electrode provided in a first region and a second region on the nitride semiconductor layer;
a drain electrode provided in the first region and the second region;
an insulating film provided in the first region and the second region between the source electrode and the drain electrode; and
a gate electrode provided in the first region and the second region on the nitride semiconductor layer between the source electrode and the drain electrode,
wherein a first distance between the source electrode and the drain electrode in a gate length direction of the first region is shorter than a second distance between the source electrode and the drain electrode in a gate length direction of the second region, and
a first length of the insulating film in the gate length direction of the first region is shorter than a second length of the insulating film in the gate length direction of the second region.

2. The device according to claim 1,
wherein the drain electrode has
a first electrode portion provided in the first region and the second region, and
a second electrode portion provided between the first electrode portion in the first region and the insulating film in the first region.

3. The device according to claim 2, wherein a film thickness of the first electrode portion is thicker than a film thickness of the second electrode portion.

4. The device according to claim 2, wherein the drain electrode has a third electrode portion provided on the insulating film between the first electrode portion in the second region and the gate electrode in the second region.

5. A semiconductor device comprising:
a nitride semiconductor layer;
a source electrode provided in a first region and a second region on the nitride semiconductor layer;
a drain electrode provided in the first region and the second region;
a first insulating film provided in the first region and the second region between the source electrode and the drain electrode;
a gate electrode provided in the first region and the second region on the nitride semiconductor layer between the source electrode and the drain electrode;
a second insulating film provided in the drain electrode in the first region separately from the first insulating film; and
a third insulating film provided in the drain electrode in the second region separately from the first insulating film and the second insulating film.

6. The device according to claim 5,
wherein the drain electrode has
a first electrode portion provided between the first region and the second region, the second insulating film and the third insulating film being provided between the first insulating film and the first electrode portion, and
a second electrode portion provided between the first insulating film in the first region and the second insulating film and between the first insulating film in the second region and the third insulating film.

7. The device according to claim 6, wherein a film thickness of the first electrode portion is thicker than a film thickness of the second electrode portion.

8. The device according to claim 6, further comprising:
a fourth insulating film provided in the drain electrode in the first region separately from the second insulating film; and
a fifth insulating film provided in the drain electrode in the first region separately from the third insulating film.

9. A semiconductor device comprising:
a nitride semiconductor layer;
a first source electrode provided in a first region and a second region on the nitride semiconductor layer;
a second source electrode provided in the first region and the second region on the nitride semiconductor layer;
a drain electrode provided in the first region and the second region between the first source electrode and the second source electrode;
a first insulating film provided in the first region and the second region between the first source electrode and the drain electrode;
a second insulating film provided in the first region and the second region between the second source electrode and the drain electrode;
a first gate electrode provided in the first region and the second region on the first insulating film; and
a second gate electrode provided in the first region and the second region on the second insulating film,
wherein a first distance between the first source electrode and the drain electrode in a gate length direction of the first region is shorter than a second distance between the first source electrode and the drain electrode in a gate length direction of the second region,
a first length of the first insulating film in the gate length direction of the first region is shorter than a second length of the second insulating film in the gate length direction of the second region,
a third distance between the second source electrode and the drain electrode in the gate length direction of the first region is shorter than a fourth distance between the second source electrode and the drain electrode in the gate length direction of the second region, and
a third length of the second insulating film in the gate length direction of the first region is shorter than a fourth length of the second insulating film in the gate length direction of the second region.

10. The device according to claim 9,
wherein the drain electrode has
a first electrode portion provided in the first region and the second region, and
a second electrode portion provided between the first electrode portion in the first region and the insulating film in the first region.

11. The device according to claim 10, wherein a film thickness of the first electrode portion is thicker than a film thickness of the second electrode portion.

12. The device according to claim 10, wherein the drain electrode has a third electrode portion provided on the insulating film between the first electrode portion in the second region and the gate electrode in the second region.
